(19) United States
(12) Patent Application Publication
(10) Pub. No.: US 2026/0215132 A1
(43) Pub. Date: Jul. 23, 2026

(54) DISPLAY DEVICE AND ELECTRONIC DEVICE INCLUDING THE DISPLAY DEVICE

(71) Applicant: Samsung Display Co., Ltd., Yongin-si (KR)

(72) Inventors: Da Song LEE, Yongin-si (KR); Jun Su PARK, Yongin-si (KR); In Tae SON, Yongin-si (KR); Kang Woo LEE, Yongin-si (KR)

(21) Appl. No.: 19/316,792

(22) Filed: Sep. 2, 2025

(30) Foreign Application Priority Data
Jan. 17, 2025 (KR) 10-2025-0007072

(51) Int. Cl. H10K 59/80

(52) U.S. Cl. CPC H10K 59/873

(57) ABSTRACT

A display device may include: a display panel; a window member on the display panel; an adhesive between the display panel and the window member; and an outer case arranged on at least one side of the display panel and the window member and containing metal, wherein the adhesive includes an alkyl acrylate compound, an acrylate compound containing a polar functional group, a hydrophobic monomer, and a hydrophilic monomer.

### CROSS-REFERENCE TO RELATED APPLICATION

The present application claims priority to and the benefit of Korean Patent Application No. 10-2025-0007072, filed on Jan. 17, 2025, in the Korean Intellectual Property Office, the entire content of which is incorporated herein by reference.

### BACKGROUND

### 1. Field

One or more embodiments of the present disclosure relate to a display device and an electronic device including a display module (e.g., a display device).

### 2. Description of the Related Art

With the advance of information-oriented society, there is an increasing demand or desire for display devices capable of presenting images in one or more suitable formats. Display devices are widely used in a range of electronic products, including but not limited to smartphones, digital cameras, laptop computers, navigation devices, and/or smart televisions.

In high-end display devices, a metal frame may be utilized or applied to enhance structural integrity and aesthetic appeal. However, if (e.g., when) subjected to external impact, the shape of the metal frame may deform, potentially causing the formation of bubbles in the adhesive utilized within the display assembly.

### SUMMARY

One or more aspects of embodiments of the present disclosure are directed toward an adhesive member having (with) improved or enhanced impact (e.g., external impact) resistance by utilizing an adhesive containing a hydrophobic monomer and a hydrophilic monomer.

However, aspects and features of embodiments of the present disclosure are not restricted to the one set forth herein. The above and other aspects and features of certain embodiments of the present disclosure will become more apparent to one of ordinary skill in the art to which the present disclosure pertains by referencing the detailed description of the present disclosure given.

Additional aspects of embodiments will be set forth in part in the description which follows and, in part, will be apparent from the description or may be learned by practice of the presented embodiments of the disclosure.

According to one or more embodiments of the present disclosure, a display device includes: a display panel; a window member on the display panel; an adhesive between the display panel and the window member; and an outer case located or arranged on at least one side of the display panel and the window member and containing metal, wherein the adhesive includes an alkyl acrylate compound, an acrylate compound containing a polar functional group, a hydrophobic monomer, and a hydrophilic monomer.

In 100 parts by weight of the adhesive, the alkyl acrylate compound may be present in an amount of 60 parts to 80 parts by weight, the acrylate compound containing the polar functional group may be present in an amount of 10 parts to 30 parts by weight, the hydrophobic monomer may be present in an amount of 3 parts to 15 parts by weight, and the hydrophilic monomer may be present in an amount of 3 parts to 15 parts by weight.

The hydrophobic monomer and the hydrophilic monomer may be present in a ratio of 5:5 to 2:8 by weight.

The adhesive may further include an emulsifier, and in 100 parts by weight of the adhesive, the emulsifier may be present in an amount of 1 part to 5 parts by weight.

An average of a difference between a modulus of a first point on a surface of the display device and a modulus of a second point spaced and/or apart (e.g., spaced apart or separated) from the first point by a set or predetermined distance may be equal to or greater than 10 MPa.

A thickness of the adhesive be in a range of 75 μm to 100 μm.

The display device may further include a black mark on an edge of one surface of the window member, wherein a thickness of the black mark may be equal to or less than 30 μm.

The adhesive may have a modulus of 0.01 MPa to 10 MPa in a frequency range of 10⁻⁴ Hz to 10³ Hz and a modulus of 10 MPa to 30 MPa in a frequency range of 10³ Hz to 10⁵ Hz.

If (e.g., when) plotting a modulus distribution according to frequency, with frequency on an x-axis (Hz) and modulus on a y-axis (MPa), an average slope in a frequency range of 10³ Hz to 10⁴ Hz be in a range of 0.01 to 0.35.

The adhesive may have two or more glass transition temperatures.

A first glass transition temperature of the adhesive be in a range of −30° C. to 0° C., and a second glass transition temperature of the adhesive be in a range of 50° C. to 80° C.

The hydrophobic monomer may contain at least one of an alkyl methacrylate compound or isobornyl acrylate.

The hydrophilic monomer may contain an acrylamide-based compound or an ester-based compound.

An adhesive strength of the adhesive may be equal to or greater than 1.5 kgf/inch.

According to one or more embodiments of the present disclosure, an electronic device includes: a display module to provide an image; and a processor to transmit an image data signal to the display module, wherein the display module includes: a display panel; a window member on the display panel; an adhesive between the display panel and the window member; and an outer case located or arranged on at least one side of the display panel and the window member and containing metal, wherein the adhesive includes an alkyl acrylate compound, an acrylate compound containing a polar functional group, a hydrophobic monomer, and a hydrophilic monomer.

In 100 parts by weight of the adhesive, the alkyl acrylate compound may be present in an amount of 60 parts to 80 parts by weight, the acrylate compound containing the polar functional group may be present in an amount of 10 parts to 30 parts by weight, the hydrophobic monomer may be present in an amount of 3 parts to 15 parts by weight, and the hydrophilic monomer may be present in an amount of 3 parts to 15 parts by weight.

An average of a difference between a modulus of a first point on a surface of the display module and a modulus of a second point spaced and/or apart (e.g., spaced apart or separated) from the first point by a set or predetermined distance may be equal to or greater than 10 MPa.

The electronic device may further include a black mark on an edge of one surface of the window member, wherein a thickness of the black mark may be equal to or less than 30 μm.

The adhesive may have a modulus of 0.01 MPa to 10 MPa in a frequency range of 10⁻⁴ Hz to 10³ Hz and a modulus of 10 MPa to 30 MPa in a frequency range of 10³ Hz to 10⁵ Hz.

If (e.g., when) plotting a modulus distribution according to frequency, with frequency on an x-axis (Hz) and modulus on a y-axis (MPa), an average slope in a frequency range of 10³ Hz to 10⁴ Hz be in a range of 0.01 to 0.35.

The adhesive according to one or more embodiments of the present disclosure may be a mixture of the hydrophobic monomer and the hydrophilic monomer, and is thus capable of dispersing impact energy generated from the outside effectively or suitably due to a difference in the transfer speed of the stress generated at the interface between a hydrophobic monomer region and a hydrophilic monomer region.

More details of one or more other embodiments are included in the detailed description and the accompanying drawings.

In one or more embodiments, because the adhesive has excellent or suitable step embedding properties, even if (e.g., when) the adhesive is applied with a thin thickness, it may completely (e.g., substantially completely) cover patterns, such as black marks.

For example, the adhesive may exhibit excellent or suitable step-embedding properties, allowing it to conform to and fill surface irregularities or height differences (e.g., steps) between adjacent layers or components. As a result, even if (e.g., when) applied in a thin layer, the adhesive may substantially or completely cover surface patterns, such as black marks or printed circuitry on the window member. This property may be advantageous or beneficial in display devices where maintaining optical uniformity (e.g., substantial uniformity) and reducing visual artifacts is important. The ability to achieve uniform (e.g., substantially uniform) coverage with a thin adhesive layer may also contribute to reduced overall device thickness and improved or enhanced manufacturing efficiency. Furthermore, the step-embedding capability of the adhesive may enhance the mechanical and optical integration between the display panel and the window member. By effectively or suitably leveling surface discontinuities, the adhesive may reduce internal stress concentrations and potential delamination points, thereby improving or enhancing long-term reliability. This feature may also support the utilization of high-resolution display panels with fine patterning, as the adhesive may accommodate and protect intricate surface features without compromising adhesion or transparency.

It should be noted that aspects and features of embodiments of the present disclosure are not limited to those described herein, and other aspects and features of certain embodiments of the present disclosure will be more apparent to those skilled in the art from the following descriptions.

### BRIEF DESCRIPTION OF THE DRAWINGS

The above and other aspects and features of certain embodiments of the present disclosure will become more apparent from the following description taken in conjunction with the accompanying drawings, in which:

FIG. 1 is a plan view of a display device according to one or more embodiments;

FIG. 2 is an exploded perspective view of a display device according to one or more embodiments;

FIG. 3 is a side view of a display device according to one or more embodiments;

FIG. 4 is a schematic cross-sectional view of a display panel according to one or more embodiments;

FIG. 5 is a diagram illustrating a black mark on one side of a window member according to one or more embodiments of the present disclosure;

FIG. 6 is a side view of a display device according to one or more embodiments;

FIG. 7 is a side view of a display device if (e.g., when) an external impact is applied to a display device according to one or more embodiments;

FIG. 8 is a side view of a display device if (e.g., when) an external impact is applied to a display device according to one or more embodiments;

FIG. 9 is a diagram illustrating arbitrary points in a window member where an adhesive member according to one or more embodiments of the present disclosure is located or arranged;

FIG. 10 is a graph illustrating the modulus (MPa) according to the frequency (Hz) of an adhesive member in one or more embodiments;

FIG. 11 is a modulus mapping image of an adhesive member according to a comparative example;

FIG. 12 is a modulus mapping image of an adhesive member according to one or more embodiments;

FIG. 13 is a graph illustrating the modulus of an adhesive member in a comparative example according to indentation depth at different temperatures;

FIG. 14 is a graph illustrating the modulus of an adhesive member in one or more embodiments according to indentation depth at different temperatures;

FIG. 15 is a top view illustrating an indented point during the evaluation of an adhesive member according to one or more embodiments;

FIG. 16 is a side view illustrating an indented point during the evaluation of an adhesive member according to one or more embodiments;

FIG. 17 is an image of a stress distribution simulation result when a force is applied to an adhesive member of a comparative example;

FIG. 18 is an image illustrating a stress distribution simulation result when a force is applied to an adhesive member of one or more embodiments;

FIG. 19 is a block diagram of an electronic device according to one or more embodiments; and

FIG. 20 is schematic views of electronic devices according to one or more suitable embodiments.

### DETAILED DESCRIPTION

The aspects and features of embodiments of the present disclosure and the methods for achieving them will become clearer with reference to one or more embodiments described herein in more detail with the accompanying drawings. However, the present disclosure is not limited to the embodiments disclosed herein, but may be implemented in one or more suitable different forms, and these embodiments are provided only to make the embodiments of the present disclosure complete and to fully inform those skilled in the art of the scope of the present disclosure, and the present disclosure is defined only by the scope of the appended claims and equivalents thereof.

The utilization of “may,” if (e.g., when) describing embodiments of the present disclosure, refers to “one or more embodiments of the present disclosure.”

In the context of the present application and unless otherwise defined, the terms “use,” “using,” and “used” may be considered synonymous with the terms “utilize,” “utilizing,” and “utilized,” respectively.

As used herein, “a,” “an,” “the,” and “at least one” do not denote a limitation of quantity and are intended to include both (e.g., simultaneously) the singular and plural, unless the context clearly indicates otherwise. For example, “an element” has substantially the same meaning as “at least one element,” unless the context clearly indicates otherwise. “At least one” is not to be construed as limiting “a” or “an.”

“About” or “approximately” as used herein is inclusive of the stated value and refers to being within an acceptable range of deviation for the particular value as determined by one of ordinary skill in the art, considering the measurement in question and the error associated with measurement of the particular quantity (e.g., the limitations of the measurement system). For example, “about” may refer to being within one or more standard deviations, or within ±30%, ±20%, ±10%, or ±5% of the stated value.

Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

In the context of the present disclosure and unless otherwise defined, plan view is an orthographic projection of a three-dimensional object from the position of a horizontal plane that intersects the object. For example, it is a top-down view, showing the layout and spatial relationships of one or more elements within the object or structure. A plan view based on a z-axis (thickness) direction refers to a top-down view of the object, as if (e.g., when) looking directly down onto the surface from above. In this context, the z-axis direction is perpendicular or normal to the horizontal plane defined by x-axis and y-axis directions.

If (e.g., when) elements or layers are referred to as being “on” or “above” another element or layer, this includes all cases where another layer or another element is directly on or directly above or in the middle of the other layer or element. In contrast, if (e.g., when) an element or a layer is referred to as being “directly on” or “directly above” another element or layer, there are no intervening layers or elements present therebetween.

The same reference numerals refer to substantially the same components throughout the specification.

The shapes, sizes, ratios, angles, numbers, and/or the like disclosed in the drawings to illustrate one or more embodiments of the present disclosure are examples, and therefore embodiments of the present disclosure are not limited to the disclosed embodiments.

It will be understood that, although the terms “first,” “second,” “third,” and/or the like may be used herein to describe one or more elements, components, regions, layers, and/or sections, these elements, components, regions, layers, and/or sections should not be limited by these terms. These terms are used to distinguish one element, component, region, layer, or section from another element, component, region, layer, or section. Thus, a first element, a first component, a first region, a first layer, or a first section as described herein may be termed a second element, a second component, a second region, a second layer, or a second section, without departing from the spirit and scope of the present disclosure.

Each of the features of the one or more suitable embodiments of the present disclosure may be partially or wholly combined or combined with each other, and one or more suitable technical connections and operations may be feasible, and each embodiment may be implemented independently of each other or may be implemented together in a related relationship.

One or more embodiments of the present disclosure will be described herein in more detail with reference to the accompanying drawings.

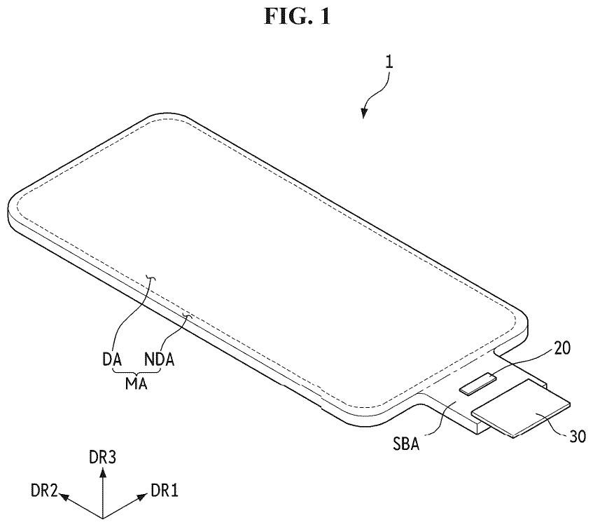

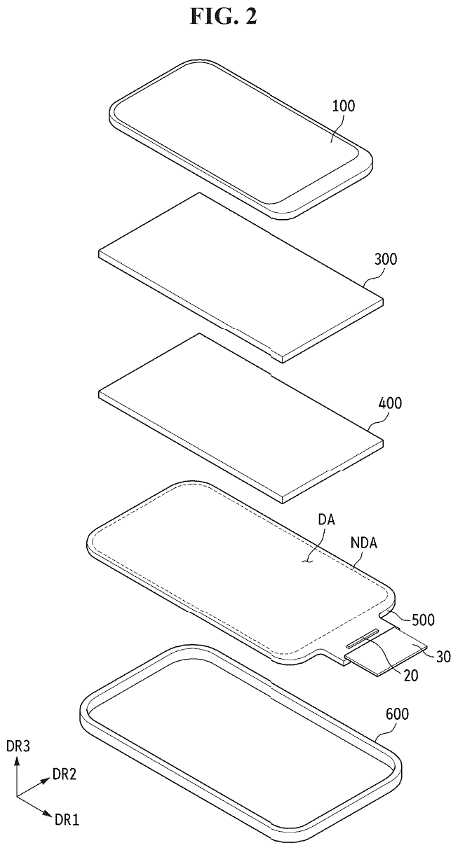

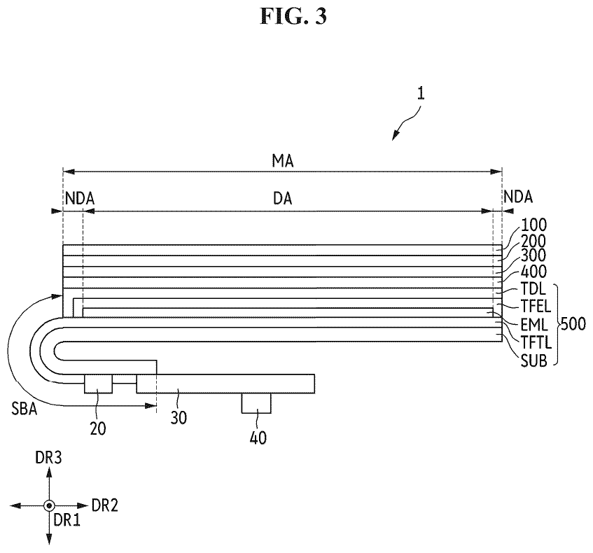

FIG. 1 is a plan view of a display device according to one or more embodiments. FIG. 2 is an exploded perspective view of a display device according to one or more embodiments. FIG. 3 is a side view of a display device according to one or more embodiments.

Referring to FIGS. 1 to 3, a display device 1 according to one or more embodiments may include a window member 100, an adhesive member 200, an anti-fingerprint film 300, an anti-reflection film 400, a display panel 500, and an outer case 600.

The display device 1 according to one or more embodiments, which is a device to display a moving image and/or a still image, may be utilized as a display screen of one or more suitable products, such as televisions, laptop computers, monitors, billboards, and the Internet of Things (IOT), as well as portable electronic devices, such as mobile phones, smart phones, tablet personal computers (tablet PCs), smart watches, watch phones, mobile communication terminals, electronic notebooks, electronic books, portable multimedia players (PMPs), navigation systems, and ultra mobile PCs (UMPCs).

The display device 1 according to one or more embodiments may be a light emitting display device, such as an organic light emitting display utilizing an organic light emitting diode, a quantum dot light emitting display including a quantum dot light emitting layer, an inorganic light emitting display including an inorganic semiconductor, and a micro or nano light emitting display utilizing a micro or nano light emitting diode (LED). In the following description, it is assumed that the display device 1 according to one or more embodiments is an organic light emitting display device, but embodiments of the present disclosure are not limited thereto.

The display device 1 may include a display panel 500, a display driving circuit 20, and a circuit board 30.

The display panel 1 may, in plan view, be in a rectangular shape (e.g., a substantially rectangular shape) having short sides in a first direction DR1 and long sides in a second direction DR2 crossing the first direction DR1. Further, the display panel 100 may have a thickness in a third direction DR3 that crosses (e.g., intersects) the first direction DR1 and the second direction DR2. The corner where the short side in the first direction DR1 and the long side in the second direction DR2 meet may be rounded to have a selected (e.g., set or predetermined) curvature or may be right-angled. The planar shape of the display panel 1 is not limited to the rectangular shape and may be in another polygonal shape (e.g., substantially polygonal shape), a circular shape (e.g., a substantially circular shape), or an elliptical shape (e.g., a substantially elliptical shape). The display panel 1 may be formed or arranged to be flat (e.g., substantially flat), but embodiments of the present disclosure are not limited thereto. For example, the display panel 1 may include a curved portion at left and right ends and having a constant (e.g., substantially constant) curvature or a varying curvature. In one or more embodiments, the display panel 1 may be flexibly so that (e.g., such that) it may be curved, bent, folded, and/or rolled.

The display panel 1 may include a main region MA and a sub-region SBA.

The main region MA may include a display area DA to display an image and a non-display area NDA that is a peripheral area of the display area DA. The display area DA may occupy most (e.g., substantially all) of the main region MA. For example, the display area DA may occupy the majority of the main region MA, and in one or more embodiments, it may extend across substantially the entire surface of the main region MA, leaving only a narrow peripheral portion for the non-display area NDA. The display area DA may be located or arranged at the center of the main region MA. The non-display area NDA may be located or arranged adjacent to the display area DA. The non-display area NDA may be an area outside (e.g., around or surrounding) the display area DA. The non-display area NDA may be located or arranged to be around (e.g., surround) the display area DA. The non-display area NDA may be an edge area of the display panel 100.

The sub-region SBA may extend in the first direction DR1 from one side of the main region MA. The length of the sub-region SBA in the first direction DR1 may be less than the length of the main region MA in the first direction DR1. The length of the sub-region SBA in the second direction DR2 may be substantially equal to or less than the length of the main region MA in the second direction DR2. The sub-region SBA may be foldable to be located or arranged under the display panel 100. In this case, the sub-region SBA may overlap the main region MA in the third direction DR3.

The display driving circuit 20 may be to generate signals and voltages to drive the display panel 1. The display driving circuit 20 may be formed or arranged as an integrated circuit (IC) and attached to the sub-region SBA of the display panel 1 by a chip on glass (COG) method, a chip on plastic (COP) method, and/or an ultrasonic bonding method. In one or more embodiments, the display driving circuit 20 may be attached onto the circuit board 30 by a chip on film (COF) method.

The circuit board 30 may be attached to one end of the sub-region SBA of the display panel 1. Thus, the circuit board 30 may be electrically connected to the display panel 1 and the display driving circuit 20. The display panel 1 and the display driving circuit 20 may be to receive digital video data, timing signals, and driving voltages through the circuit board 30. The circuit board 30 may be a flexible printed circuit board, a printed circuit board, or a flexible film, such as a chip on film.

A touch driving circuit 40 may be located or arranged on the circuit board 30. The touch driving circuit 40 may be formed or arranged as an integrated circuit (IC) and attached to the circuit board 30.

The touch driving circuit 40 may be electrically connected to a plurality of driving electrodes and a plurality of sensing electrodes of the touch sensing layer TDL. The touch driving circuit 40 may apply a touch driving signal to the plurality of driving electrodes and sense a touch sensing signal of each of the plurality of touch nodes, for example, a charge change amount of mutual capacitance through the plurality of sensing electrodes. The touch driving circuit 40 may be to determine whether the user's touch has been made, whether the user is in proximity, and/or the like, according to the touch sensing signal of each of the plurality of touch nodes. The user's touch refers to that an object, such as a user's finger and/or pen, is in direct contact with the front surface of the display device 1 on the touch sensing layer TDL. The user's approach refers to that an object, such as a pen and/or a user's finger, is positioned away from the front surface of the display device 1, such as hovering.

The window member 100 may be attached to the front surface of the anti-fingerprint film 300 by the adhesive member 200. The window member 100 may include a transparent (e.g., substantially transparent) material, and for example, may be glass and/or plastic. For example, the window member 100 may be an ultra thin glass (UTG) having a thickness of 0.1 mm or less and/or a transparent (e.g., substantially transparent) polyimide film.

The adhesive member 200 may be an optically clear (e.g., substantially transparent) adhesive film and/or an optically clear (e.g., substantially transparent) resin. For example, the adhesive member 200 may include a clear (e.g., substantially transparent) adhesive, such as a pressure sensitive adhesive (PSA), and/or an optically clear (e.g., substantially transparent) adhesive (OCA). Because the adhesive member 200 is a main or predominant feature of one or more embodiments of the present disclosure, a more detailed description thereof will be given herein.

The anti-fingerprint film 300 may be placed or arranged on the front surface of the window member 100. The anti-fingerprint film 300 may serve to prevent fingerprints of a user using the display device 1 from being left on it (or reduce a degree to or occurrence of which fingerprints of a user using the display device 1 are left on it).

The anti-reflection film 400 may be placed or arranged on the front surface of the display panel 500. The anti-reflection film 400 may include two or more refractive layers having different refractive indices. The anti-reflection film 400 may be to reduce reflected light (e.g., a degree or occurrence of reflected light) through the two or more refractive layers. The anti-reflection film 400 may be arranged in two or more layers by stacking high refractive layers and low refractive layers alternately utilizing the distributed Bragg reflector (DBR) characteristics.

The refractive index of the low refractive layer may be 1.20 to 1.60, but embodiments of the present disclosure are not limited thereto. The low refractive layer may include at least one of a silicon resin, silica, or silicon oxide (e.g., SiOₓ, wherein 0<x≤2; e.g., SiO₂), but embodiments of the present disclosure are not limited thereto. The low refractive layer is not limited to the materials as described in one or more embodiments but may be any suitable material that achieves a low refractive index.

The refractive index of the high refractive layer may be 1.70 to 2.80, but embodiments of the present disclosure are not limited thereto. The high refractive layer may contain at least one of silicon nitride (Si₃N₄), aluminum nitride (AlN), zirconium nitride (ZrN), chromium nitride (CrN), titanium nitride (TiN), manganese nitride (Mn₄N), iron nitride (FeNₓ), cobalt nitride (CoNₓ), nickel nitride (Ni₃N), copper nitride (Cu₃N), zinc nitride (Zn₂N₃), vanadium nitride (VN), molybdenum nitride (Mo₂N), hafnium nitride (HfN), germanium nitride (Ge₃N₄), lead nitride (Pb(N₃)₂), titanium niobate (Ti₄Nb₃O₃₅), titanium dioxide (TiO₂), zirconium dioxide (ZrO₂), lithium niobate (LiNbO₃), lithium tantalate (LiTaO₃), or lanthanum titanium (LaTiO₂). The high refractive layer is not limited to the materials as described in one or more embodiments but may be any suitable material that achieves a high refractive index.

The thickness of the low refractive layer and the thickness of the high refractive layer may be substantially the same or different. The thickness of the low refractive layer and the thickness of the high refractive layer may be determined in consideration of the characteristics of the anti-reflection film 400, such as target reflection wavelength, hardness, durability, and reflectivity.

A light blocking layer to absorb light incident from the outside, a buffer layer to absorb impact from the outside, and a heat dissipation layer to efficiently or suitably dissipate heat from the display panel 500 may further be located or arranged under the display panel 500.

The light blocking layer may be to block the transmission of light, thereby preventing the components arranged below the light blocking layer from being viewed from above the display panel 500 (or reducing a degree to or occurrence of which the components arranged below the light blocking layer are viewed from above the display panel 500). The light blocking layer may include a light absorbing material, such as a black pigment, black dyes and/or the like.

The buffer layer may be to absorb an external impact to prevent the display panel 500 from being damaged (or reduce a degree to or occurrence of which the display panel 500 is damaged). The buffer layer may be formed or arranged as a single layer or two or more layers. For example, the buffer layer may include a polymer resin, such as polyurethane (PU), polycarbonate (PC), polypropylene (PP), and/or polyethylene (PE) or may include an elastic material, such as sponge obtained by foam-molding rubber, a urethane-based material, and/or an acrylic-based material.

The heat dissipation layer may include a first heat dissipation layer containing graphite, carbon nanotubes, and/or the like, and a second heat dissipation layer containing a metal thin film containing, for example, copper, nickel, ferrite, and/or silver which may shield electromagnetic waves and has excellent or suitable thermal conductivity.

The outer case 600 may be to accommodate the anti-fingerprint film 300, the anti-reflection film 400, and the display panel 500, and may be combined with the window member 100. The outer case 600 may be to protect the components accommodated in the outer case 600. The outer case 600 may be located or arranged on at least one side of the display panel 500 and the window member 100. For example, the outer case 600 may be positioned to cover, enclose, or frame at least one lateral or peripheral side of both the display panel 500 and the window member 100. In the drawing, the outer case is illustrated to form a frame-like structure that is around (e.g., surrounds) the sides of the stacked components, providing mechanical protection and structural support. For example, the outer case 600 may be located or arranged along at least one lateral side of the display panel 500 and the window member 100, for example, in the form of a frame that is around (e.g., surrounds) or partially encloses their edges. The outer case 600 may be provided in the form of a frame around (e.g., surrounding) the lateral sides of the display panel 500 and the window member 100. The outer case 600 may be to protect the lateral sides of the display panel 500 and the window member 100.

The outer case 600 may include metal. If (e.g., when) the outer case 600 is made of metal, it may provide a more luxurious feel than if (e.g., when) utilizing plastic material.

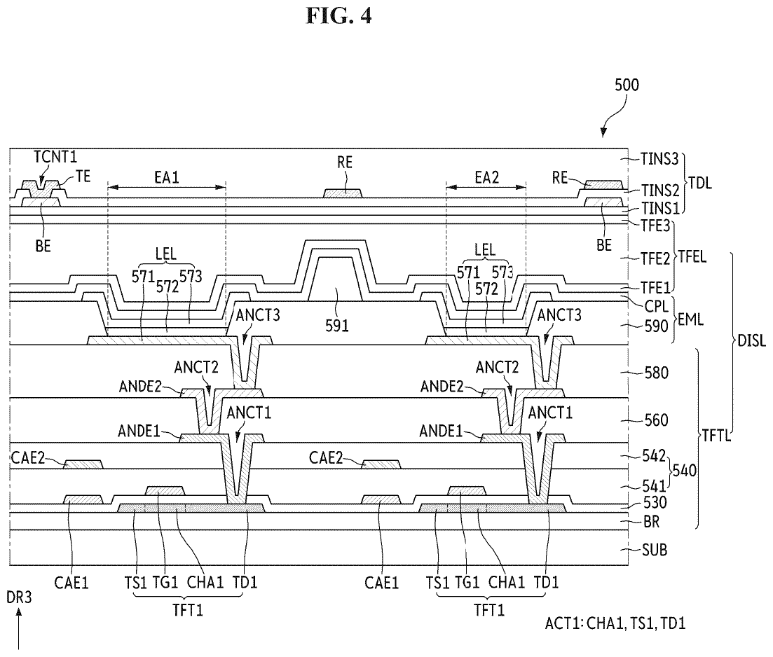

FIG. 4 is a schematic cross-sectional view of a display panel of one or more embodiments.

Referring to FIG. 4, the display panel 500 may include a substrate SUB, a display layer DISL on the substrate SUB, and a touch sensing layer TDL on the display layer DISL. The display layer DISL may include a thin film transistor layer TFTL, a light emitting element layer EML, and an encapsulation layer TFEL.

The thin film transistor layer TFTL may be located or arranged on the substrate SUB. The thin film transistor layer TFTL may include a barrier film BR, a thin film transistor TFT1, a first capacitor electrode CAE1, a second capacitor electrode CAE2, a first anode connection electrode ANDE1, a second anode connection electrode ANDE2, a gate insulating film 530, a first interlayer insulating film 541, a second interlayer insulating film 542, a first planarization film 560, and a second planarization film 580.

The substrate SUB may include an insulating (e.g., electrically insulating) material, such as a polymer resin. For example, the substrate SUB may include polyimide. The substrate SUB may be a flexible substrate which may be bent, folded, or rolled.

The barrier film BR may be located or arranged on the substrate SUB. The barrier film BR may be a film to protect thin film transistors of the thin film transistor layer TFTL and a light emitting layer 572 of the light emitting element layer EML from moisture permeating through the substrate SUB which is susceptible to moisture permeation. The barrier film BR may be formed or arranged as a plurality of inorganic films that are alternately stacked. For example, the barrier film BR may be formed or arranged as two or more films in which one or more inorganic films of a silicon nitride layer, a silicon oxynitride layer, a silicon oxide layer, a titanium oxide layer, and an aluminum oxide layer are alternately stacked.

The thin film transistor layer TFTL may be located or arranged on the substrate SUB. The thin film transistor layer TFTL may be arranged in the main region MA and the sub-region SBA. The thin film transistor layer TFTL may include thin film transistors.

The thin film transistor TFT1 may be located or arranged on the barrier film BR. An active layer ACT1 of the thin film transistor TFT1 may be located or arranged on the barrier film BR. The active layer ACT1 of the thin film transistor TFT1 may include polycrystalline silicon, monocrystalline silicon, low-temperature polycrystalline silicon, amorphous (e.g., non-crystalline) silicon, and/or an oxide semiconductor.

The active layer ACT1 may include a channel region CHA1, a source region TS1, and a drain region TD1. The channel region CHA1 may be a region overlapping a gate electrode TG1 in the third direction DR3 that is the thickness direction of the substrate SUB. The source region TS1 may be located or arranged on one side of the channel region CHA1, and the drain region TD1 may be located or arranged on the other side of the channel region CHA1. The source region TS1 and the drain region TD1 may be regions that do not overlap the gate electrode TG1 in the third direction DR3. The source region TS1 and the drain region TD1 may be regions having conductivity (e.g., electrical conductivity) by doping a silicon semiconductor or an oxide semiconductor with ions or impurities.

The gate insulating film 530 may be located or arranged on the active layer ACT1 of the thin film transistor TFT1. The gate insulating film 530 may be formed or arranged as an inorganic film, for example, a silicon nitride layer, a silicon oxynitride layer, a silicon oxide layer, a titanium oxide layer, or an aluminum oxide layer.

The gate electrode TG1 of the thin film transistor TFT1 and the first capacitor electrode CAE1 may be located or arranged on the gate insulating film 530. The gate electrode TG1 may overlap the channel region CHA1 in the third direction DR3. FIG. 4 illustrates that the gate electrode TG1 and the first capacitor electrode CAE1 are spaced and/or apart (e.g., spaced apart or separated) from each other, but the gate electrode TG1 and the first capacitor electrode CAE1 may be connected to each other and formed or arranged integrally. The gate electrode TG1 and the first capacitor electrode CAE1 may be formed or arranged as a single layer or two or more layers containing any one selected from among molybdenum (Mo), aluminum (Al), chromium (Cr), gold (Au), titanium (Ti), nickel (Ni), neodymium (Nd), and copper (Cu) or an alloy thereof.

The first interlayer insulating film 541 may be located or arranged on the gate electrode TG1 and the first capacitor electrode CAE1 of the thin film transistor TFT1. The first interlayer insulating film 541 may be formed or arranged as an inorganic film, for example, a silicon nitride layer, a silicon oxynitride layer, a silicon oxide layer, a titanium oxide layer, or an aluminum oxide layer. The first interlayer insulating film 541 may be formed or arranged as a plurality of inorganic films.

The second capacitor electrode CAE2 may be located or arranged on the first interlayer insulating film 541. The second capacitor electrode CAE2 may overlap the first capacitor electrode CAE1 of the thin film transistor TFT1 in the third direction DR3. Further, if (e.g., when) the gate electrode TG1 and the first capacitor electrode CAE1 are formed or arranged integrally, the second capacitor electrode CAE2 may overlap the gate electrode TG1 in the third direction DR3. Because the first interlayer insulating film 541 has a selected (e.g., set or predetermined) dielectric constant, a capacitor may be formed or arranged by the first capacitor electrode CAE1, the second capacitor electrode CAE2, and the first interlayer insulating film 541 between the first capacitor electrode CAE1 and the second capacitor electrode CAE2. The second capacitor electrode CAE2 may be formed or arranged as a single layer or two or more layers containing any one selected from among molybdenum (Mo), aluminum (Al), chromium (Cr), gold (Au), titanium (Ti), nickel (Ni), neodymium (Nd) and copper (Cu), or an alloy thereof.

A second interlayer insulating film 542 may be located or arranged on the second capacitor electrode CAE2. The second interlayer insulating film 542 may be formed or arranged as an inorganic film, for example, a silicon nitride layer, a silicon oxynitride layer, a silicon oxide layer, a titanium oxide layer, or an aluminum oxide layer. The second interlayer insulating film 542 may be formed or arranged as a plurality of inorganic films.

The first anode connection electrode ANDE1 may be located or arranged on the second interlayer insulating film 542. The first anode connection electrode ANDE1 may be connected to the drain region TD1 of the thin film transistor TFT1 through a first connection contact hole ANCT1 penetrating the gate insulating film 530, the first interlayer insulating film 541, and the second interlayer insulating film 542. The first anode connection electrode ANDE1 may be formed or arranged as a single layer or two or more layers containing any one selected from among molybdenum (Mo), aluminum (Al), chromium (Cr), gold (Au), titanium (Ti), nickel (Ni), neodymium (Nd), and copper (Cu), or an alloy thereof.

The first planarization film 560 to flatten a stepped portion formed or arranged by the thin film transistor TFT1 may be located or arranged on the first anode connection electrode ANDE1. The first planarization film 560 may be formed or arranged as an organic film made of a resin, such as an acryl resin, an epoxy resin, a phenolic resin, a polyamide resin, a polyimide resin, and/or the like.

The second anode connection electrode ANDE2 may be located or arranged on the first planarization film 560. The second anode connection electrode ANDE2 may be connected to the first anode connection electrode ANDE1 through a second connection contact hole ANCT2 penetrating the first planarization film 560. The second anode connection electrode ANDE2 may be formed or arranged as a single layer or two or more layers containing any one selected from among molybdenum (Mo), aluminum (Al), chromium (Cr), gold (Au), titanium (Ti), nickel (Ni), neodymium (Nd), and copper (Cu), or an alloy thereof.

The second planarization film 580 may be located or arranged on the second anode connection electrode ANDE2. The second planarization film 180 may be formed or arranged as an organic film made of a resin, such as an acryl resin, epoxy resin, a phenolic resin, a polyamide resin, a polyimide resin, and/or the like.

The light emitting element layer EML may be located or arranged on the thin film transistor layer TFTL. The light emitting element layer EML may be arranged in the display area DA of the main region MA. The light emitting element layer EML may include light emitting elements arranged in emission portions.

The light emitting element layer EML including light emitting elements LEL and a bank 590 may be located or arranged on the second planarization film 580. Each of the light emitting elements LEL may include a pixel electrode 571, the light emitting layer 572, and a common electrode 573.

The pixel electrode 571 may be located or arranged on the second planarization film 580. The pixel electrode 571 may be connected to a second anode connection electrode ANDE2 through a third connection contact hole ANCT3 penetrating the second planarization film 580.

In a top emission structure that emits light toward the common electrode 573 with respect to the light emitting layer 572, the pixel electrode 571 may include a metal material having high reflectivity, such as a stacked structure (Ti/AI/Ti) of aluminum (AI) and titanium (Ti), a stacked structure (ITO/AI/ITO) of aluminum (AI) and indium tin oxide (ITO), a stacked structure (ITO/Ag/ITO) of silver (Ag) and ITO, an APC alloy, and a stacked structure (ITO/APC/ITO) of an APC alloy and ITO. The APC alloy may be an alloy of silver (Ag), palladium (Pd), and copper (Cu).

The bank 590 may be formed or arranged to partition the pixel electrode 571 on the second planarization film 580, in order to define an emission portion EA1 and EA2. The bank 590 may be located or arranged to cover the edge of the pixel electrode 571. The bank 590 may be formed or arranged as an organic film made of a resin, such as an acryl resin, an epoxy resin, a phenolic resin, a polyamide resin, a polyimide resin, and/or the like.

Each of the first emission portion EA1 and the second emission portion EA2 may be an area in which the pixel electrode 571, the light emitting layer 572, and the common electrode 573 are sequentially stacked, and holes from the pixel electrode 571 and electrons from the common electrode 573 are recombined in the light emitting layer 572 to emit light.

The light emitting layer 572 may be located or arranged on the pixel electrode 571 and the bank 590. The light emitting layer 572 may include an organic material to emit light of a selected (e.g., set or predetermined) color. For example, the light emitting layer 572 may include a hole transporting layer, an organic material layer, and an electron transporting layer.

The common electrode 573 may be located or arranged on the light emitting layer 572. The common electrode 573 may be located or arranged to cover the light emitting layer 572. The common electrode 573 may be a common layer formed or arranged commonly in the first emission portion EA1 and the second emission portion EA2.

In the top emission structure, the common electrode 573 may include a transparent (e.g., substantially transparent) conductive (e.g., electrically conductive) oxide (TCO) material, such as ITO and/or IZO, capable of transmitting light or a semi-transmissive conductive (e.g., electrically conductive) material, such as magnesium (Mg), silver (Ag), or an alloy of magnesium (Mg) and silver (Ag). If (e.g., when) the common electrode 173 includes a semi-transmissive conductive (e.g., electrically conductive) material, the light emission efficiency may be increased or enhanced due to a micro-cavity effect.

A spacer 591 may be located or arranged on the bank 590. The spacer 591 may serve to support a mask during the fabricating process of fabricating the light emitting layer 572. The spacer 591 may be formed or arranged as an organic film made of a resin, such as an acryl resin, an epoxy resin, a phenolic resin, a polyamide resin, a polyimide resin, and/or the like.

In one or more embodiments, the display panel 500 may further include a capping layer CPL on the common electrode 573. The capping layer CPL may include an inorganic material. For example, the capping layer CPL may contain at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride.

The encapsulation layer TFEL may be located or arranged on the light emitting element layer EML. The encapsulation layer TFEL may be arranged in the display area DA and the non-display area NDA of the main region MA. The encapsulation layer TFEL may include at least one inorganic layer and at least one organic layer to encapsulate the light emitting element layer.

The encapsulation layer TFEL may be located or arranged on the common electrode 573. The encapsulation layer TFEL may include at least one inorganic film to prevent oxygen and/or moisture from permeating (or reduce a degree to or occurrence of which oxygen and/or moisture permeate) into the light emitting element layer EML. In one or more embodiments, the encapsulation layer TFEL may include at least one organic film to protect the light emitting element layer EML from foreign substances, such as dust. For example, the encapsulation layer TFEL may include a first encapsulation inorganic film TFE1, an encapsulation organic film TFE2, and a second encapsulation inorganic film TFE3.

The first encapsulation inorganic film TFE1 may be located or arranged on the common electrode 573, the encapsulation organic film TFE2 may be located or arranged on the first encapsulation inorganic film TFE1, and the second encapsulation inorganic film TFE3 may be located or arranged on the encapsulation organic film TFE2. The first encapsulation inorganic film TFE1 and the second encapsulation inorganic film TFE3 may be formed or arranged as two or more films in which one or more inorganic films of a silicon nitride layer, a silicon oxynitride layer, a silicon oxide layer, a titanium oxide layer, and an aluminum oxide layer are alternately stacked. The encapsulation organic film TFE2 may be an organic film made of a resin, such as an acryl resin, an epoxy resin, a phenolic resin, a polyamide resin, a polyimide resin, and/or the like.

The touch sensing layer TDL may be located or arranged on the encapsulation layer TFEL. The touch sensing layer TDL may include a first touch insulating film TINS1, the connection electrode BE, a second touch insulating film TINS2, the driving electrode TE, the sensing electrode RE, and a third touch insulating film TINS3. The touch sensing layer TDL may be to sense a touch of a person or an object utilizing touch electrodes.

The first touch insulating film TINS1 may be located or arranged on the encapsulation layer TFEL. The first touch insulating film TINS1 may be formed or arranged as an inorganic film, for example, a silicon nitride layer, a silicon oxynitride layer, a silicon oxide layer, a titanium oxide layer, or an aluminum oxide layer.

The connection electrode BE may be located or arranged on the first touch insulating film TINS1. The connection electrode BE may be formed or arranged as a single layer or two or more layers containing any one selected from among molybdenum (Mo), aluminum (AI), chromium (Cr), gold (Au), titanium (Ti), nickel (Ni), neodymium (Nd), and copper (Cu), or an alloy thereof.

The second touch insulating film TINS2 may be located or arranged on the connection electrode BE. The second touch insulating film TINS2 may be formed or arranged as an inorganic film, for example, a silicon nitride layer, a silicon oxynitride layer, a silicon oxide layer, a titanium oxide layer, or an aluminum oxide layer. In one or more embodiments, the second touch insulating film TINS2 may be formed or arranged as an organic film made of a resin, such as an acryl resin, an epoxy resin, a phenolic resin, a polyamide resin, a polyimide resin, and/or the like.

The driving electrodes TE and the sensing electrodes RE may be located or arranged on the second touch insulating film TINS2. The driving electrodes TE and the sensing electrodes RE may be formed or arranged as a single layer or two or more layers containing any one selected from among molybdenum (Mo), aluminum (AI), chromium (Cr), gold (Au), titanium (Ti), nickel (Ni), neodymium (Nd), and copper (Cu), or an alloy thereof.

The driving electrode TE and the sensing electrode RE may overlap the connection electrode BE in the third direction DR3. The driving electrode TE may be connected to the connection electrode BE through a touch contact hole TCNT1 penetrating the first touch insulating film TINS1.

The third touch insulating film TINS3 may be formed or arranged on the driving electrodes TE and the sensing electrodes RE. The third touch insulating film TINS3 may serve to flatten the stepped portion formed or arranged by the driving electrodes TE, the sensing electrodes RE, and the connection electrodes BE. The third touch insulating film TINS3 may be formed or arranged as an organic film made of a resin, such as an acryl resin, an epoxy resin, a phenolic resin, a polyamide resin, a polyimide resin, and/or the like.

Hereinafter, one or more suitable embodiments of the adhesive member 200, which is a main or predominant feature of the display device 1 according to one or more embodiments of the present disclosure, will be described in more detail with reference to the accompanying drawings.

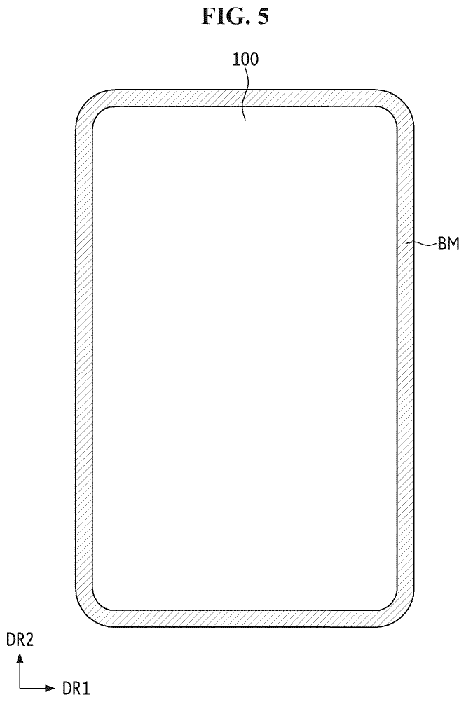

FIG. 5 is a diagram illustrating a black mark placed or arranged on one side of a window member according to one or more embodiments of the present disclosure.

Referring to FIG. 5, a black mark BM may be positioned or arranged along the edge of the window member 100.

The black mark BM may be formed or arranged in the non-display area NDA of the window member 100. The black mark BM may be provided with a receiver to allow the user to hear the other party's voice during a phone call. The receiver may be covered by a receiver grill to protect the interior of the receiver from the outside.

The thickness of the black mark BM may be equal to or less than 30 μm.

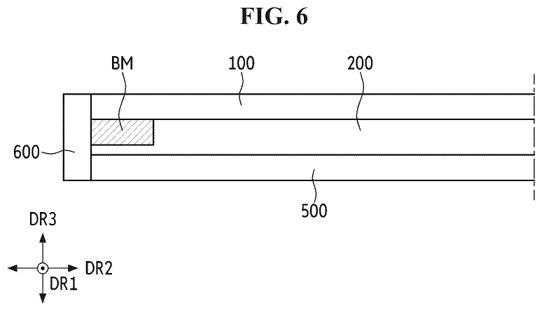

FIG. 6 is a side view of a display device according to one or more embodiments.

Referring to FIG. 6, the display panel 500 may be placed or arranged opposite to the direction in which the black mark BM is located or arranged in the window member 100. The display panel 500 and the window member 100 may be bonded by the adhesive member 200. The outer case 600 may be placed or arranged on the lateral side of the window member 100, the display panel 500, and the adhesive member 200.

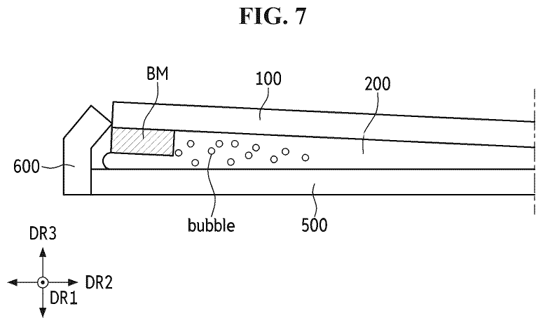

FIG. 7 is a side view of a display device if (e.g., when) an external impact is applied to a display device according to one or more embodiments.

Referring to FIG. 7, if (e.g., when) the display device 1 receives an external impact, such as being dropped, the outer case 600 may undergo deformation. The deformation of the outer case 600 may cause the window member 100, which has been in contact with the outer case 600, to lift. As the window member 100 lifts, stress may be generated in the adhesive member 200. If (e.g., when) stress exceeding the yield point is applied to the adhesive member 200, cohesion failure may occur and bubbles may form (or may be generated) inside the adhesive member 200.

If (e.g., when) the display device 1 receives impact from the outside, the modulus of the adhesive material 200 may increase. With such increase of the modulus, the stress applied to the adhesive member 200 may increase, and the bubbles formed or generated in the adhesive member 200 may be distributed up to the display area DA. For example, the larger the modulus, the wider the area where the bubbles are formed or generated in the adhesive member 200.

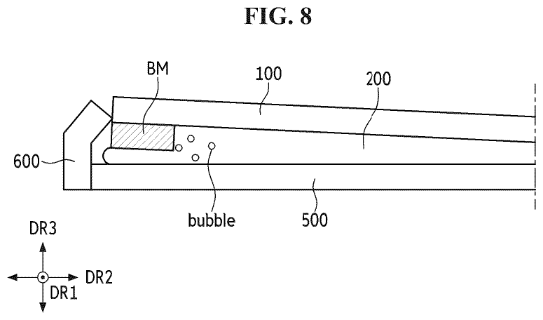

FIG. 8 is a side view of a display device if (e.g., when) an external impact is applied to a display device according to one or more embodiments.

FIG. 8 is a diagram illustrating a case where the adhesive member 200 utilizing an adhesive of the present disclosure is utilized. The adhesive according to one or more embodiments of the present disclosure may be a mixture of a hydrophobic monomer and a hydrophilic monomer, and may thus be capable of dispersing impact energy generated from the outside effectively or suitably due to a difference in the transfer speed of the stress generated at the interface between a hydrophobic monomer region and a hydrophilic monomer region. Accordingly, the area where the bubbles are formed or generated in the adhesive member 200 may be reduced. It is illustrated that the area where the bubbles are formed or generated in FIG. 8 is smaller than the area where the bubbles are formed or generated in FIG. 7.

For example, the adhesive including the hydrophobic monomer and the hydrophilic monomer may cause phase separation between the hydrophobic monomer and the hydrophilic monomer because the hydrophobic monomer and the hydrophilic monomer are immiscible. The modulus and glass transition temperature may be different between the region where the hydrophobic monomer is distributed and the region where the hydrophilic monomer is distributed.

The glass transition temperature of the region where the hydrophobic monomer is distributed may be in the range of 50° C. to 80° C., and the glass transition temperature of the region where the hydrophilic monomer is distributed may be in the range of −30° C. to 0° C.

Because the modulus differs between the region where the hydrophobic monomer is distributed and the region where the hydrophilic monomer is distributed, stress and impact energy applied from the outside may be effectively or suitably dispersed. For example, if (e.g., when) the stress is transferred from the hydrophobic monomer to the hydrophilic monomer, the transfer speed of the stress may decrease or reduce. Due to the difference in the transfer speed of the stress generated at the interface between the hydrophilic monomer region and the hydrophobic monomer region, the impact energy generated from the outside may be reduced or dispersed.

The adhesive member 200 of the present disclosure may include an adhesive, and the adhesive may include an alkyl acrylate compound, an acrylate compound including a polar functional group, a hydrophobic monomer, and a hydrophilic monomer.

The alkyl acrylate compound may be an alkyl acrylate containing an alkyl group having 1 to 20 carbon atoms. For example, the alkyl acrylate compound may be at least one of alkyl acrylate containing a linear alkyl group having 1 to 12 carbon atoms or alkyl acrylate containing a branched alkyl group having 3 to 12 carbon atoms. For example, the alkyl acrylate containing the linear alkyl group having 1 to 12 carbon atoms may be one selected from among n-hexyl acrylate, n-octyl acrylate, n-nonyl acrylate, butyl acrylate, and/or the like, but embodiments of the present disclosure are not limited thereto. For example, the alkyl acrylate containing the branched alkyl group having 3 to 12 carbon atoms may be one selected from among 2-ethylhexyl acrylate, iso-nonyl acrylate, iso-octyl acrylate, and/or the like, but embodiments of the present disclosure are not limited thereto.

The alkyl acrylate compound may form a main chain of the adhesive. In 100 parts by weight of the adhesive, the alkyl acrylate compound may be included in an amount of 60 parts to 80 parts by weight.

The acrylate compound containing the polar functional group may improve or enhance interfacial adhesion and have excellent or suitable reactivity with a crosslinking agent, facilitating the introduction of a crosslinking structure.

The polar functional group may include at least one of a hydroxyl group, an epoxy group, or a urethane group.

The acrylate compound containing the polar functional group may include at least one of 2-hydroxy ethyl (meth)acrylate, 2-hydroxy propyl (meth)acrylate, 4-hydroxy butyl (meth)acrylate, 6-hydroxy hexyl (meth)acrylate, 8-hydroxy octyl (meth)acrylate, 10-hydroxy decyl (meth)acrylate, or 12-hydroxy lauryl (meth)acrylate.

In 100 parts by weight of the adhesive, the acrylate compound containing the polar functional group may be included in an amount of 10 parts to 30 parts by weight.

The hydrophobic monomer may include at least one of an alkyl methacrylate compound or isobornyl acrylate. In 100 parts by weight of the adhesive, the hydrophobic monomer may be included in an amount of 3 parts to 15 parts by weight.

The hydrophilic monomer may include an acrylamide-based compound or an ester-based compound.

The acrylamide-based compound may also include (meth)acrylamides having an amino group, such as N-ethyl (meth)acrylamide, N-isopropyl (meth)acrylamide, N-n-butyl (meth)acrylamide, N-octyl (meth)acrylamide, dimethylaminoethyl (meth)acrylamide, diethylaminoethyl (meth)acrylamide, and dimethylaminopropyl (meth)acrylamide. The N,N-dialkyl (meth)acrylamide as described herein may include, by way of non-limiting example, at least one of N,N-dimethyl (meth)acrylamide, N,N-diethyl (meth)acrylamide, N,N-dipropyl (meth)acrylamide, N,N-diisopropyl (meth)acrylamide, N,N-di(n-butyl) (meth)acrylamide, N,N-di(t-butyl) (meth)acrylamide, N-methylol (meth)acrylamide, N-(2-hydroxyethyl) (meth)acrylamide, N-(2-hydroxypropyl) (meth)acrylamide, N-(1-hydroxypropyl) (meth)acrylamide, N-(3-hydroxypropyl) (meth)acrylamide, N-(2-hydroxybutyl) (meth)acrylamide, N-(3-hydroxybutyl) (meth)acrylamide, N-(4-hydroxybutyl) (meth)acrylamide, N-methyl-N-2-hydroxyethyl (meth)acrylamide, N-methoxymethyl (meth)acrylamide, or N-butoxymethyl (meth)acrylamide.

The ester-based compound may include at least one of 2-propenoic acid, (5-ethyl-1,3-dioxan-5-yl)methyl ester, or 2-phenoxyethyl ester.

The adhesive may further include an additive that is generally available or generally used in the art to control adhesive strength, cohesion, viscosity, elastic modulus, glass transition temperature, and/or the like. For example, the adhesive may include, as the additive, a tackifier, an antioxidant, an anti-corrosion agent, a leveling agent, a surface lubricant, a dye, a pigment, an anti-foaming agent, a filler, a photoinitiator, a light stabilizer, a plasticizer, and/or the like.

The hydrophobic monomer and the hydrophilic monomer may be included in a content (e.g., amount) ratio of 5:5 to 2:8 by weight.

If (e.g., when) the content (e.g., amount) of the hydrophobic monomer is too low compared to the content (e.g., amount) of the hydrophilic monomer, the punching property may be reduced. The punching property refers to the degree of indentation and/or scratching that occurs if (e.g., when) a blade is applied from one side to the other during a cutting process. The less the occurrence of indentation and/or scratching during the cutting process, the better the punching performance is evaluated. Also, haze may increase.

If (e.g., when) the content (e.g., amount) of the hydrophilic monomer is too low compared to the content (e.g., amount) of the hydrophobic monomer, impact resistance may be reduced. Impact energy may be reduced in the hydrophilic monomer region, but if (e.g., when) the content (e.g., amount) of the hydrophilic monomer is low, there may be a limit in sufficiently reducing the impact energy.

The adhesive may further contain an emulsifier, and the emulsifier may be included in an amount of 1 part to 5 parts by weight in 100 parts by weight of the adhesive. If (e.g., when) the amount of the emulsifier is more than 5 parts by weight with respect to 100 parts by weight of the adhesive, the adhesive property and the modulus may increase or enhance, which may result in a decrease or reduction in the impact resistance and the ability to cover the step of the black mark BM.

The emulsifier may include at least one of polyoxyethylene (20) sorbitan monolaurate, 2-[4-(2,4,4-trimethylpentan-2-yl)phenoxy]ethanol, polyethylene oxide alkyl aryl ether, polyethylene oxide alkyl amine, or polyethylene oxide alkyl ester.

The adhesive may have a modulus of 0.01 MPa to 10 MPa in a frequency range of 10⁻⁴ Hz to 10³ Hz and a modulus of 10 MPa to 30 MPa in a frequency range of 10³ Hz to 10⁵ Hz.

The frequency of the display device 1 may be 10⁻⁴ Hz to 10³ Hz in general, and the frequency range if (e.g., when) the display device 1 is subjected to external impact, such as being dropped, may be 10³ Hz to 10⁵ Hz. Therefore, the modulus of the display device 1, if (e.g., when) it is in a normal state, may be 0.01 MPa to 10 MPa, and the modulus of the display device 1, if (e.g., when) it is subjected to impact, may be 10 MPa to 30 MPa.

A commercially available adhesive may have a modulus of 50 MPa or higher in the frequency range of 10³ Hz to 10⁵ Hz. This refers to that the impact resistance is low.

In contrast, the adhesive member 200 to which the adhesive of the present disclosure is applied may have a modulus of 10 MPa to 30 MPa in the frequency range of 10³ Hz to 10⁵ Hz if (e.g., when) the display device 1 is subjected to external impact.

The adhesive of the present disclosure may be considered to have high impact resistance.

If (e.g., when) plotting the modulus distribution according to frequency, with frequency on the x-axis (Hz) and modulus on the y-axis (MPa), the average slope in the frequency range of 10³ Hz to 10⁴ Hz may be in the range of 0.01 to 0.35.

If (e.g., when) the display device 1 is subjected to external impact under normal conditions, the slope of the modulus with respect to the frequency may remain low, in a range of approximately 0.01 to 0.35 in the range of 10³ Hz to 10⁴ Hz where the frequency increases rapidly. This may refer to that the modulus increases gradually if (e.g., when) the external impact is applied to the display device 1.

The adhesive of the present disclosure may have high impact resistance, so the minimum load at which a defect, such as bubbles, occurs may be 25 N or more.

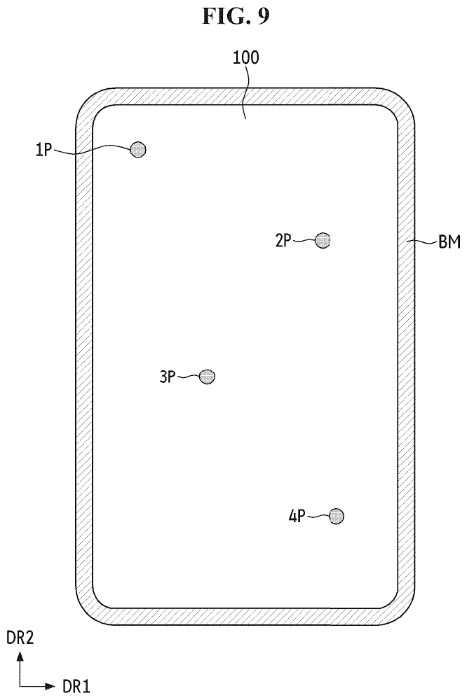

FIG. 9 is a diagram illustrating arbitrary points in a window member where an adhesive member according to one or more embodiments of the present disclosure is located or arranged.

For example, a first point 1P, a second point 2P, a third point 3P, and a fourth point 4P of FIG. 9 may be points randomly marked on the window member where the adhesive member 200 is located or arranged. If (e.g., when) measuring the modulus of the first to fourth points 1P to 4P, the average of a modulus difference between the first point 1P and the second point 2P, a modulus difference between the first point 1P and the third point 3P, a modulus difference between the first point 1P and the fourth point 4P, a modulus difference between the second point 2P and the third point 3P, a modulus difference between the second point 2P and the fourth point 4P, and a modulus difference between the third point 3P and the fourth point 4P may be 10 MPa or more. For example, if (e.g., when) the modulus measured at the first point 1P is 5 MPa, the modulus measured at the third point 3P may be 20 MPa.

The second point 2P may be spaced and/or apart (e.g., spaced apart or separated) from the first point 1P by a selected (e.g., set or predetermined) distance. The selected distance may be approximately 0.5 cm.

The adhesive member 200 may include an adhesive including a hydrophobic monomer and a hydrophilic monomer, and the modulus may differ between a region where the hydrophobic monomer is distributed and a region where the hydrophilic monomer is distributed. The modulus of the region where the hydrophilic monomer is distributed may be smaller than the modulus of the region where the hydrophobic monomer is distributed.

In the window member 100 where the adhesive member 200 is located or arranged, differences in modulus may occur across different regions, allowing stress and impact energy to be dispersed or shock wave transmission to be reduced at the interface between regions with different moduli.

The thickness of the adhesive may be 75 μm to 100 μm.

An adhesive that is generally available or generally used may be applied in a thickness of 150 μm or more. For example, if (e.g., when) the black mark BM is formed or arranged with a thickness of 30 μm, the adhesive may need to be or may be desired to be formed or arranged with a thickness of at least 150 μm to completely (e.g., substantially completely) cover the black mark BM.

In contrast, even if (e.g., when) the black mark BM is formed or arranged with a thickness of 30 μm, the adhesive of the present disclosure may be formed or arranged with a thickness of 100 μm to completely (e.g., substantially completely) cover the black mark BM.

The adhesive strength of the adhesive may be equal to or greater than 1.5 kgf/inch.

The adhesive of the present disclosure may achieve both (e.g., simultaneously) high fluidity and high adhesive strength. The adhesive of the present disclosure may exhibit excellent or suitable step embedding properties even in small amounts, ensuring superior lamination property if (e.g., when) placed between the window member 100 and the display panel 500. The superior lamination property may refer to that the empty space between the patterned surface of an element and the adhesive member 200 is minimized or reduced and the patterned surface is completely (e.g., substantially completely) filled without bubbles, so that (e.g., such that) the surface in contact with the adhesive member 200 is firmly attached.

One or more embodiments of the present disclosure will be described in more detail through the following examples, but the following examples are only for the purpose of description and not intended to limit the scope of the present disclosure.

### EXAMPLES

### 1. Preparation of Adhesive

### 1) Preparation Example 1

70 parts by weight of 2-ethylhexyl acrylate, 20 parts by weight of 2-hydroxyethyl acrylate, 5 parts by weight of isobornyl acrylate, and 5 parts by weight of dimethyl acrylamide were added to a reaction vessel. An adhesive was prepared by mixing the solutions in the reaction vessel.

### 2) Example 1

The adhesive prepared in Preparation Example 1 was applied to a glass substrate with a selected (e.g., set or predetermined) thickness, dried, and cured to prepare an adhesive member.

### 3) Example 2

The adhesive prepared in Preparation Example 1 was applied with a thickness of 75 μm onto a glass substrate with a 20 μm-thick black mark printed on the edges, and dried at 120° C. for 4 minutes to perform primary curing. Subsequently, a glass substrate was stacked on the applied adhesive to prepare an adhesive member.

### 4) Example 3

An adhesive member was prepared in substantially the same manner as in Example 2, except that the adhesive prepared in Preparation Example 1 was applied with a thickness of 100 μm.

### 5) Example 4

The adhesive prepared in Preparation Example 1 was applied with a thickness of 75 μm onto a glass substrate and dried for 4 minutes to perform primary curing. Subsequently, a PET film was stacked on the applied adhesive and UV was irradiated to perform secondary curing. The PET film and the glass substrate were removed, leaving only the adhesive member.

### 6) Example 5

An adhesive member was prepared in substantially the same manner as in Example 4, except that the adhesive prepared in Preparation Example 1 was applied with a thickness of 100 μm.

### 7) Comparative Example 1

As a comparative example, the CEF30 series from 3M was used as an adhesive, and an adhesive member was prepared on a glass substrate in substantially the same manner as in Example 1.

### 8) Comparative Example 2

An adhesive member was prepared in substantially the same manner as in Example 2, except that the CEF30 series from 3M was used as the adhesive.

### 9) Comparative Example 3

An adhesive member was prepared in substantially the same manner as in Comparative Example 2, except that the adhesive was applied with a thickness of 100 μm.

### 10) Comparative Example 4

An adhesive member was prepared in substantially the same manner as in Comparative Example 2, except that the adhesive was applied with a thickness of 150 μm.

### 11) Comparative Example 5

An adhesive member was prepared in substantially the same manner as in Example 4, except that the CEF30 series from 3M was used as the adhesive.

### 12) Comparative Example 6

An adhesive member was prepared in substantially the same manner as in Comparative Example 5, except that the adhesive was applied with a thickness of 100 μm.

### 13) Comparative Example 7

An adhesive member was prepared in substantially the same manner as in Comparative Example 5, except that the adhesive was applied with a thickness of 150 μm.

### Evaluation

### 1. Modulus Evaluation

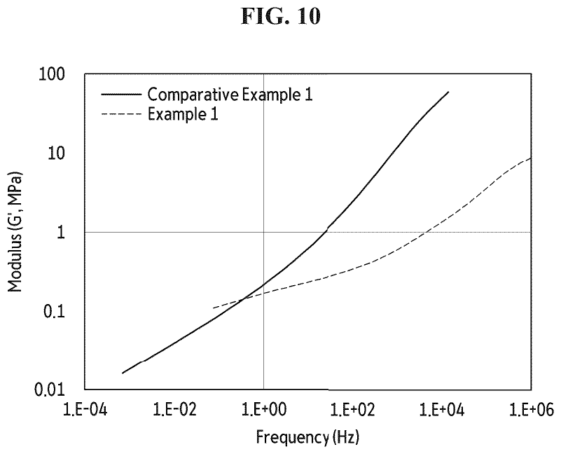

The moduli of the adhesive members of Example 1 and Comparative Example 1 were measured using an indenter, and the results are shown in FIGS. 10 to 14.

FIG. 10 is a graph illustrating the modulus (MPa) according to the frequency (Hz) of an adhesive member in one or more embodiments.

As can be seen from the result shown in FIG. 10, the modulus of the adhesive member of Comparative Example 1 increases rapidly in the frequency range of 10³ Hz to 10⁴ Hz, which is an impact range. Additionally, it is observed that the modulus is equal to or greater than 50 MPa at around 10³ Hz. In contrast, it is observed that the adhesive member of Example 1 has a modulus gradually increasing in the frequency range of 10³ Hz to 10⁴ Hz, which is an impact range, and has a very low modulus of about 10 MPa at a frequency of about 10⁶ Hz. This refers to that the adhesive of the present disclosure has high impact resistance.

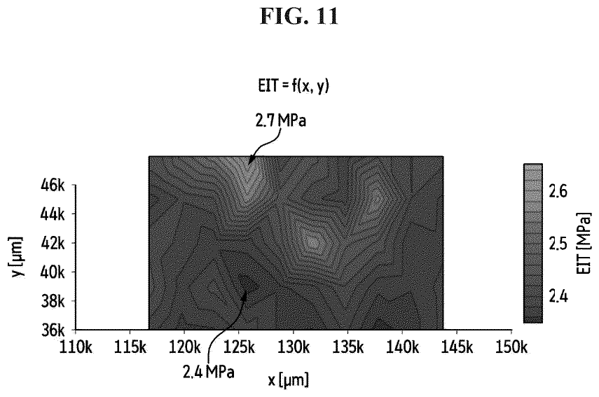

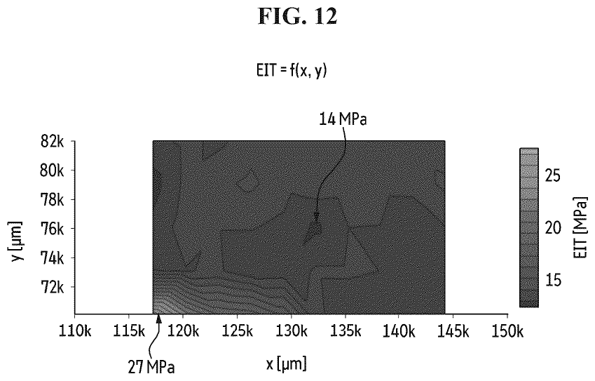

FIG. 11 is a modulus mapping image of an adhesive member according to a comparative example. FIG. 12 is a modulus mapping image of an adhesive member according to one or more embodiments.

As can be seen from the result shown in FIG. 11, a first point (the brightest point) and a second point (the darkest point) of the adhesive member are 2.7 MPa and 2.5 MPa, respectively. Additionally, the mapping range is indicated as 2.3 MPa to 2.7 MPa.

In contrast, according to the result shown in FIG. 12, a first point (the brightest point) and a second point (the darkest point) of the adhesive member are found to be 14 MPa and 27 MPa, respectively. Additionally, it may be confirmed that the mapping range display shows a range of 10 MPa or more, from 14 MPa to 27 MPa.

According to the results shown in FIGS. 11 and 12, the adhesive member of Comparative Example 1 exhibits a substantially uniform modulus across its plane, whereas the adhesive member of Example 1 exhibits variations in modulus across its plane. If (e.g., when) there is a difference in modulus across the plane, as in Example 1, shock wave dissipation may occur at the interface where the modulus varies. Accordingly, the adhesive member may be considered to have excellent or suitable impact resistance.

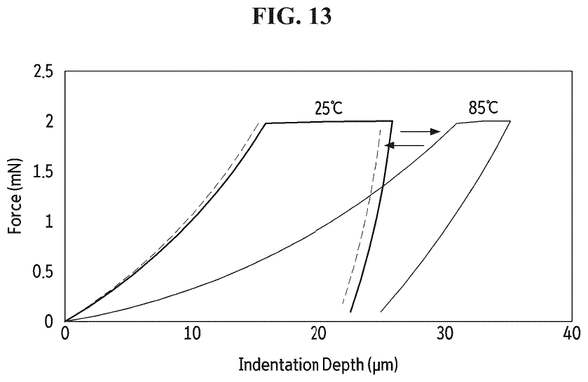

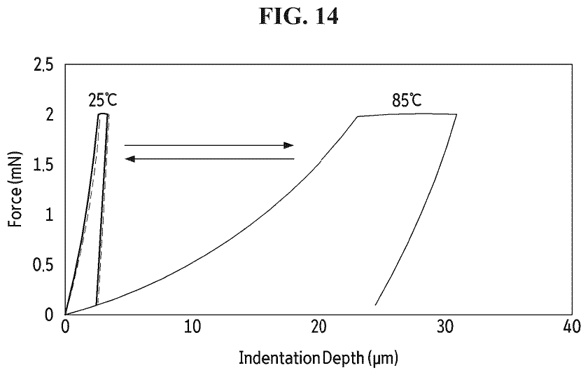

The modulus was evaluated under temperature sweep conditions, and the results are shown in FIGS. 13 and 14.

FIG. 13 is a graph illustrating the modulus of an adhesive member in a comparative example according to indentation depth at different temperatures. FIG. 14 is a graph illustrating the modulus of an adhesive member in one or more embodiments according to indentation depth at different temperatures.

According to the result shown in FIG. 13, the adhesive member of Comparative Example 1 exhibits only a small difference in modulus at different temperatures. In contrast, according to the result shown in FIG. 14, the adhesive member of Example 1 exhibits a significant difference in modulus at different temperatures. In the case of Example 1, phase separation may occur due to incomplete mixing between the hydrophobic monomer and the hydrophilic monomer, which may result in the presence of two or more glass transition temperatures. Shock wave dissipation may occur at the interface between the hydrophobic monomer region and the hydrophilic monomer region, leading to improved or enhanced impact resistance of the adhesive member.

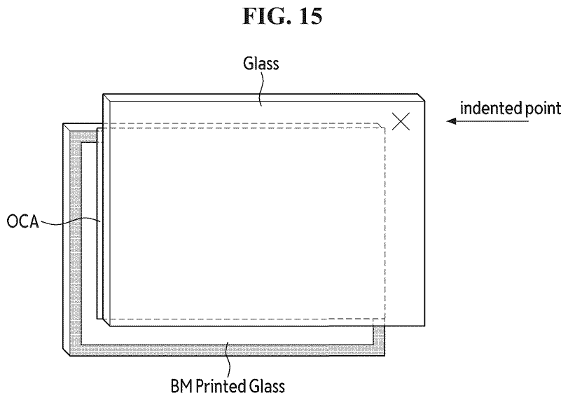

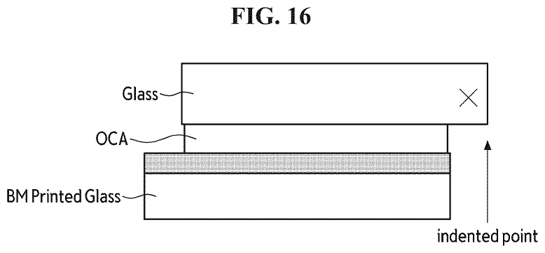

To evaluate crack formation and bubble generation in an adhesive, an indentation test was conducted using a universal testing machine (UTM). The physical properties of the adhesive members of Example 2, Example 3, Comparative Example 2, Comparative Example 3, and Comparative Example 4 when they were slowly pressed at indented points of FIGS. 15 and 16 were presented in Table 1.

FIG. 15 is a top view illustrating an indented point during the evaluation of an adhesive member according to one or more embodiments. FIG. 16 is a side view illustrating an indented point during the evaluation of an adhesive member according to one or more embodiments.

TABLE 1

| | | Room | | | Bubble |
|---|---|---|---|---|---|
| | Thickness | Temperature | −20° C. | | Formation |
| | (μm) | G′ (MPa) | G′ (MPa) | T_{g} (° C.) | Load (/N) |
| Example 2 | 75 | 1.27 | 5.17 | −30 and 60 | 28.1 ± 1.94 |
| Example 3 | 100 | 1.30 | 5.25 | −30 and 60 | 30.4 ± 6.39 |
| Comparative | 75 | 0.08 | 6.38 | −13 | 21.7 ± 2.82 |
| Example 2 | | | | | |
| Comparative | 100 | 0.22 | 240.97 | 5 | 15.0 ± 1.15 |
| Example3 | | | | | |
| Comparative | 150 | 0.22 | 241.00 | 5 | 23.9 ± 1.83 |
| Example 4 | | | | | |

According to the results shown in Table 1, each of Examples 2 and 3 is found to have two glass transition temperatures (T_{g}) of −30° C. and 60° C., whereas Comparative Examples 2, 3, and 4 each have a single glass transition temperature (T_{g}) and their temperatures are −13° C., 5° C., and 5° C., respectively.

At room temperature, the moduli of Examples 2 and 3 and Comparative Examples 2 to 4 do not show significant differences (though the room-temperature moduli of Examples 2 and 3 are slightly higher). However, the moduli at low temperatures are different. For example, the moduli at low temperatures in Examples 2 and 3 are 5.17 MPa and 5.25 MPa, respectively, while the moduli at low temperatures in Comparative Examples 3 and 4 are 240.97 MPa and 241.00 MPa, respectively, which are very high. The load at which bubble formation begins in Comparative Example 3 is approximately 15.0 N. Comparative Example 2, which has a modulus of approximately 6.38 at the low temperature, exhibits a bubble formation load of around 21.7 N. The bubble formation load of Comparative Example 4 is approximately 23.9 N. The bubble formation load of Comparative Example 4 is higher than those of Comparative Examples 2 and 3, which have smaller adhesive thicknesses than Comparative Example 4. However, the bubble formation load of Comparative Example 4 is found to be lower than those of Examples. Because Comparative Examples 2, 3, and 4 all have low bubble formation loads, they may be considered to have low impact resistance. In contrast, Examples 2 and 3 have high bubble formation loads of 28.1 N and 30.4 N, respectively.

Examples 2 and 3 each have two glass transition temperatures (T_{g}) and exhibit low modulus and high impact resistance even at low temperatures.

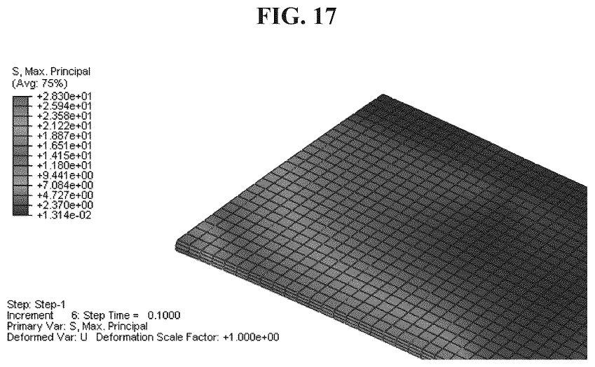

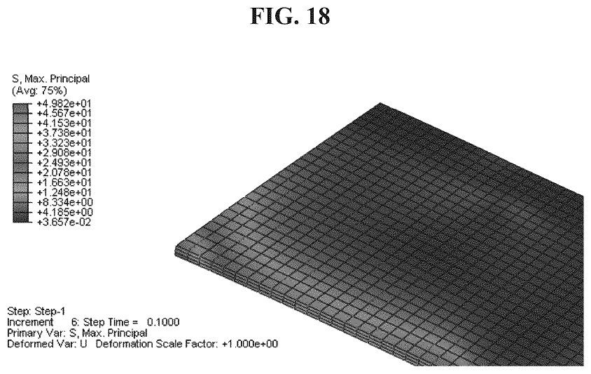

FIG. 17 is an image of a stress distribution simulation result when a force is applied to an adhesive member of a comparative example. FIG. 18 is an image illustrating a stress distribution simulation result when a force is applied to an adhesive member of one or more embodiments.

As can be seen from the result shown in FIG. 17, when a force is applied to the adhesive member of the comparative example, the stress transfer distance is relatively large. In contrast, the adhesive member of the embodiment in FIG. 18 shows a reduced stress transfer distance when a force is applied.

The adhesive member prepared in the embodiment has hydrophobic and hydrophilic monomer regions randomly distributed, which reduces the transfer speed of shock waves, thereby decreasing the stress transfer distance.

### 2. Step Embedding Property

To evaluate the step embedding property of an adhesive, the adhesive members of Examples 4 and 5 and Comparative Examples 5, 6, and 7 were placed on top surfaces of glass substrates with patterns of 10 μm, 20 μm, and 30 μm in thickness, respectively, and then laminated by autoclave processing at 40° C. and 5 bar for 10 minutes. The laminated surface was examined under a microscope to check for the presence of bubbles. The results of the microscopic evaluation were categorized as OK if no bubbles are present and NG if any bubbles are detected. These results are presented in Table 2.

TABLE 2

| | |
|---|---|
| Thickness of | Step Embedding Property |
| Adhesive | (Thickness of Pattern) |

| | Member (μm) | 10 μm | 20 μm | 30 μm |
|---|---|---|---|---|
| Example 4 | 75 | OK | OK | NG |
| Example 5 | 100 | OK | OK | OK |
| Comparative | 75 | OK | NG | NG |
| Example 5 | | | | |
| Comparative | 100 | OK | OK | NG |
| Example 6 | | | | |
| Comparative | 150 | OK | OK | OK |
| Example 7 | | | | |

According to the results shown in Table 2, the step embedding property of the adhesive member in Example 4, which has a thickness of 75 μm, is 20 μm, whereas the step embedding property of Comparative Example 5 is 10 μm. The step embedding property of the adhesive member in Example 5, which has a thickness of 100 μm, is 30 μm, whereas the step embedding property of Comparative Example 6 is 20 μm. If (e.g., when) utilizing the adhesive of the comparative example, the adhesive member needs and is desired to have a minimum thickness of 150 μm to achieve step embedding properties. In contrast, if (e.g., when) utilizing the adhesive of the embodiment, it is confirmed that even with a thickness of 100 μm, the adhesive member exhibits good or suitable step embedding properties for a 30 μm-thick pattern. Therefore, the adhesive member of the embodiment may effectively or suitably cover steps of a thick pattern even with a smaller thickness compared to the adhesive member of the comparative example. This proves that the adhesive member of the embodiment has superior step embedding properties.

### 3. Adhesive Strength

Adhesive strength was measured according to the JIS 2107 standard as 180° adhesive strength between an adhesive member and a glass plate (alkali-free glass plate). The adhesive members of Examples 4 and 5 and Comparative Example 7 were each laminated onto a glass plate. Using a 30 kgf load cell, each of the glass plate and the adhesive member was connected to an upper jig and a lower jig of a tensile testing machine (Texture Analyzer, TA Instrument). A load (adhesive strength) was measured while separating the adhesive member from the glass plate at a tensile speed of 300 mm/min, a tensile angle of 180°, and a tensile temperature of 25° C., and the results are presented in Table 3.

TABLE 3

| | Thickness of Adhesive | Adhesive |
|---|---|---|
| | Member (μm) | Strength (kgf/in) |
| Example 4 | 75 | 2.0 |
| Example 5 | 100 | 2.3 |
| Comparative Example 7 | 150 | 2.9 |

According to the results shown in Table 3, it may be confirmed that the adhesive strength of the adhesive member of the example is excellent or suitable, with an adhesive strength of 1.5 kgf/in or more.

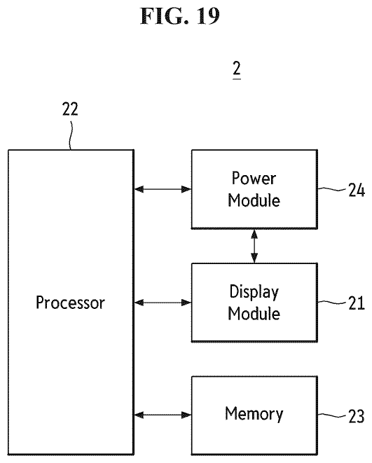

FIG. 19 is a block diagram of an electronic device according to one or more embodiments. Referring to FIG. 19, an electronic device 2 according to one or more embodiments may include a display module 21, a processor 22, a memory 23, and a power module 24.

The processor 22 may include at least one of a central processing unit (CPU), an application processor (AP), a graphic processing unit (GPU), a communication processor (CP), an image signal processor (ISP), or a controller.

The memory 23 may be to store data information desired or required for the operation of the processor 22 or the display module 21. If (e.g., when) the processor 22 executes an application stored in the memory 23, an image data signal and/or an input control signal may be transmitted to the display module 21, and the display module 21 may process the received signal and output image information through a display screen.

The power module 24 may include a power supply module, such as a power adapter and/or a battery device, and a power conversion module that is to convert the power supplied by the power supply module to generate the power desired or required for the operation of the electronic device 20.

At least one selected from among the components of the electronic device 2 as described in one or more embodiments may be included in the display device 1 as described in one or more embodiments. Further, one or more of individual modules functionally included in one module may be included in the display device 1 and one or more others may be provided separately from the display device 1. For example, the display device 1 may include the display module 21, and the processor 22, the memory 23, and the power module 24 may be provided in the form of other devices in the electronic device 2 other than the display device 1.

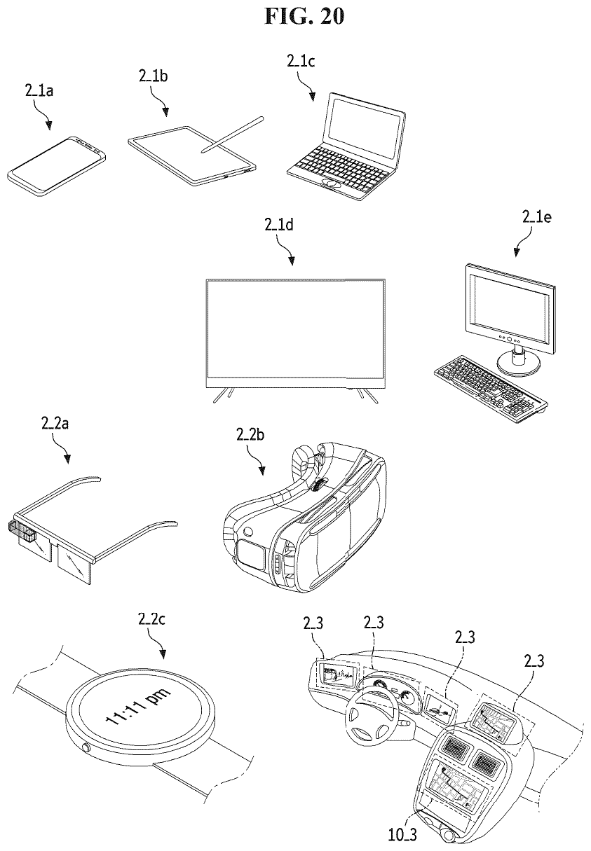

FIG. 20 is schematic views of electronic devices according to one or more suitable embodiments.

Referring to FIG. 20, one or more suitable electronic devices 2 to which the display device according to one or more embodiments is applied may include not only an image display electronic device, such as a smartphone 2_1a, a tablet PC 2_1b, a laptop 2_1c, a TV 2_1d, and a desk monitor 2_1e, but also a wearable electronic device including a display module, such as smart glasses 2_2a, a head mounted display 2_2b, a smart watch 2_2c, and/or the like, a vehicle electronic device 2_3 including a display module, such as a center information display (CID) on a dashboard, a center fascia, and an instrument panel of a car, a room mirror display, and/or the like.

A light-emitting device, a display device, a display apparatus, an electronic device, an electronic apparatus, a device for manufacturing substantially the same and/or any other relevant devices or components according to one or more embodiments of the present disclosure may be implemented by utilizing any suitable hardware, firmware (e.g., an application-specific integrated circuit), software, or a (e.g., any suitable) combination of software, firmware, and hardware. For example, the one or more components of the device may be provided on one integrated circuit (IC) chip or on separate IC chips. Further, the one or more components of the device may be implemented on a flexible printed circuit film, a tape carrier package (TCP), and/or a printed circuit board (PCB), or provided on one substrate. Further, the one or more components of the device may be a process or thread, running on one or more processors, in one or more computing devices, executing computer program instructions and interacting with other system components for performing the one or more functionalities described herein. The computer program instructions may be stored in a memory which may be implemented in a computing device utilizing a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more computing devices may be combined or integrated into a single computing device, or the functionality of a particular computing device may be distributed across one or more other computing devices without departing from the scope of the present disclosure.

Although one or more embodiments of the present disclosure have been described with reference to the accompanying drawings, those skilled in the art will understand that the present disclosure can be embodied in one or more suitable forms without departing from the spirit and scope of the present disclosure. Therefore, it should be understood that the embodiments as described herein are to be considered in all respects as illustrative and not restrictive.

What is claimed is:

1. A display device comprising:
a display panel;
a window member on the display panel;
an adhesive between the display panel and the window member; and
an outer case on at least one side of the display panel and the window member and comprising metal,
wherein the adhesive comprises an alkyl acrylate compound, an acrylate compound comprising a polar functional group, a hydrophobic monomer, and a hydrophilic monomer.

2. The display device as claimed in claim 1, wherein in 100 parts by weight of the adhesive,
the alkyl acrylate compound is in an amount of 60 parts to 80 parts by weight,
the acrylate compound comprising the polar functional group is in an amount of 10 parts to 30 parts by weight,
the hydrophobic monomer is in an amount of 3 parts to 15 parts by weight, and
the hydrophilic monomer is in an amount of 3 parts to 15 parts by weight.

3. The display device as claimed in claim 1, wherein the hydrophobic monomer and the hydrophilic monomer are in a ratio of 5:5 to 2:8 by weight.

4. The display device as claimed in claim 1, wherein the adhesive further comprises an emulsifier, and
in 100 parts by weight of the adhesive, the emulsifier is in an amount of 1 part to 5 parts by weight.

5. The display device as claimed in claim 1, wherein an average of a difference between a modulus of a first point on a surface of the display device and a modulus of a second point spaced from the first point by a set distance is equal to or greater than 10 MPa.

6. The display device as claimed in claim 1, wherein a thickness of the adhesive is in a range of 75 μm to 100 μm.

7. The display device as claimed in claim 6, further comprising a black mark on an edge of one surface of the window member,
wherein a thickness of the black mark is equal to or less than 30 μm.

8. The display device as claimed in claim 1, wherein the adhesive has a modulus of 0.01 MPa to 10 MPa in a frequency range of 10⁻⁴ Hz to 10³ Hz and a modulus of 10 MPa to 30 MPa in a frequency range of 10³ Hz to 10⁵ Hz.

9. The display device as claimed in claim 1, wherein when plotting a modulus distribution according to frequency, with frequency on an x-axis (Hz) and modulus on a y-axis (MPa), an average slope in a frequency range of 10³ Hz to 10⁴ Hz is in a range of 0.01 to 0.35.

10. The display device as claimed in claim 1, wherein the adhesive has two or more glass transition temperatures.

11. The display device as claimed in claim 10, wherein:
a first glass transition temperature of the adhesive is in a range of −30° C. to 0° C., and
a second glass transition temperature of the adhesive is in a range of 50° C. to 80° C.

12. The display device as claimed in claim 1, wherein the hydrophobic monomer comprises at least one of an alkyl methacrylate compound or isobornyl acrylate.

13. The display device as claimed in claim 1, wherein the hydrophilic monomer comprises an acrylamide-based compound or an ester-based compound.

14. The display device as claimed in claim 1, wherein an adhesive strength of the adhesive is equal to or greater than 1.5 kgf/inch.

15. An electronic device comprising:
a display module to provide an image; and
a processor to transmit an image data signal to the display module,
wherein the display module comprises:
a display panel;
a window member on the display panel;
an adhesive between the display panel and the window member; and
an outer case on at least one side of the display panel and the window member and comprising metal,
wherein the adhesive comprises an alkyl acrylate compound, an acrylate compound comprising a polar functional group, a hydrophobic monomer, and a hydrophilic monomer.

16. The electronic device as claimed in claim 15, wherein in 100 parts by weight of the adhesive,
the alkyl acrylate compound is in an amount of 60 parts to 80 parts by weight,
the acrylate compound comprising the polar functional group is in an amount of 10 parts to 30 parts by weight,
the hydrophobic monomer is in an amount of 3 parts to 15 parts by weight, and
the hydrophilic monomer is in an amount of 3 parts to 15 parts by weight.

17. The electronic device as claimed in claim 15, wherein an average of a difference between a modulus of a first point on a surface of the display module and a modulus of a second point spaced from the first point by a set distance is equal to or greater than 10 MPa.

18. The electronic device as claimed in claim 15, further comprising a black mark on an edge of one surface of the window member,
wherein a thickness of the black mark is equal to or less than 30 μm.

19. The electronic device as claimed in claim 15, wherein the adhesive has a modulus of 0.01 MPa to 10 MPa in a frequency range of 10⁴ Hz to 10³ Hz and a modulus of 10 MPa to 30 MPa in a frequency range of 10³ Hz to 10⁵ Hz.

20. The electronic device as claimed in claim 15, wherein when plotting a modulus distribution according to frequency, with frequency on an x-axis (Hz) and modulus on a y-axis (MPa), an average slope in a frequency range of 10³ Hz to 10⁴ Hz is in a range of 0.01 to 0.35.
